(19) United States
(12) Patent Application Publication
(10) Pub. No.: US 2026/0332164 A1
(43) Pub. Date: Oct. 22, 2026

(54) METHOD AND APPARATUS FOR DECODING USING OPTIMIZED WEIGHT OF NEURAL NETWORK MODEL BASED ON SPATIALLY COUPLED LOW-DENSITY PARITY-CHECK CODE

(71) Applicants: SEOUL NATIONAL UNIVERSITY R&DB FOUNDATION, Seoul (KR); University of Ulsan Foundation for Industry Cooperation, Ulsan (KR); RESEARCH & BUSINESS FOUNDATION SUNGKYUNKWAN UNIVERSITY, Suwon-si (KR); POSTECH Research and Business Development Foundation, Pohang-si (KR)

(72) Inventors: Daeyoung YUN, Ulsan (KR); Jongseon NO, Seoul (KR); Heeyoul KWAK, Ulsan (KR); Sanghyo KIM, Suwon-si (KR); Yongjune KIM, Pohang-si (KR)

(73) Assignees: SEOUL NATIONAL UNIVERSITY R&DB FOUNDATION, Seoul (KR); University of Ulsan Foundation for Industry Cooperation, Ulsan (KR); RESEARCH & BUSINESS FOUNDATION SUNGKYUNKWAN UNIVERSITY, Suwon-si (KR); POSTECH Research and Business Development Foundation, Pohang-si (KR)

(21) Appl. No.: 19/326,892

(22) Filed: Sep. 12, 2025

(30) Foreign Application Priority Data
Apr. 21, 2025 (KR) 10-2025-0051362

(51) Int. Cl. H03M 13/11; G06N 3/08

(52) U.S. Cl. CPC H03M 13/1111; G06N 3/08

(57) ABSTRACT

An SC-LDPC-based decoding apparatus according to one embodiment may perform an operation of modeling a belief propagation (BP) message transmission process according to a preset number of iterations of BP calculations in a Tanner graph including check nodes, variable nodes, and messages between each node for SC-LDPC decoding as a layer of a neural network to generate a neural network-based LDPC decoder; an operation of setting a damping factor that adjusts a ratio between a previous message and a current message transmitted from a check node to a variable node to determine whether to activate the check node in repeatedly carrying out BP calculations according to the number of iterations; an operation of dividing nodes and edges of the neural network into a preset number of groups to set a window, which is a unit in which a decoding process is performed, and separately setting a first weight, which is used when a decoding result of the previous window is an error occurrence, and a second weight, which is used when the decoding result of the previous window is normal, to mitigate error propagation between windows; and an operation of training the decoder based on training data including information on a codeword.

### BACKGROUND OF THE INVENTION

### Field of the Invention

The present disclosure relates to a neural network decoder based on a spatially coupled low-density parity-check (SC-LDPC) code, and more particularly, to a technology that optimizes a weight of an SC-LDPC-based neural network model to improve the decoding performance of an SC-LDPC code.

Meanwhile, this application was supported by the following national research development projects.

[Project Identification Number] 2710008295

[Project Number] 00398449

[Name of Ministry] Ministry of Science and ICT

[Name of Project Management (Specialized) Organization] Institute for Information & Communication Technology Planning & Evaluation

[Name of Research Program] Broadcasting and Communication Industry Technology Development

[Research Project Name] Network Research Center (NRC): Channel Code Decoding and Channel Estimation Technology for Communication Generation Evolution

[Name of Project Performing Organization] Pohang University of Science and Technology

[Research Period] Apr. 1, 2024 to Dec. 31, 2024

[National Research and Development Project That Supported This Invention]

[Project Identification Number] 2710008125

[Project Number] 00229849

[Name of Ministry] Ministry of Science and ICT

[Name of Project Management (Specialized) Organization] Institute for Information & Communication Technology Planning & Evaluation

[Name of Research Program] PIM Artificial Intelligence Semiconductor Core Technology Development (Design)

[Research Project Name] eFLASH Foundry Process Based on IoT Intelligence

MPU/Connectivity/Lightweight Neural Network Integrated Semiconductor Development

[Name of Project Performing Organization] Pohang University of Science and Technology

[Research Period] Jan. 1, 2024 to Dec. 31, 2024

### Background of the Related Art

Error correction codes are a key technology that ensures high reliability in a communication system. An error correction code technology is implemented through an encoder and a decoder, in which the encoder generates a codeword using given information bits and their corresponding parity bits, and the decoder restores the original information bits from an error or loss that has occurred during the transmission process.

Well-known error-correction codes include a Bose-Chaudhuri-Hocquenghem (BCH) code, a Reed-Solomon (RS) code, a Turbo code, and a low-density parity-check (LDPC) code. Among them, LDPC has been widely used in a recent communication system due to its excellent error correction capability and low decoding complexity.

In particular, a spatially coupled low-density parity-check (SC-LDPC) code, which is a type of LDPC code, is attracting attention because of its excellent error correction capability and low-latency decoding. SC-LDPC codes are generated by concatenating multiple single LDPC codes. Decoding of SC-LDPC codes is performed by exchanging messages between a check node (CN) and a variable node (VN) in a graph, and a window decoding technique is used in this process. Window decoding, which is a method that allows low-latency decoding of SC-LDPC codes, performs decoding within each window while sequentially moving windows.

However, an existing SC-LDPC technology has several problems.

First, in window decoding, only a subset of target variable nodes needs to be decoded; accordingly, updates for all nodes need not be performed. Nevertheless, conventional window decoding executes all updates uniformly, thereby introducing unnecessary operations that increase decoding complexity and power consumption.

In addition, in the existing SC-LDPC technology, an error propagation problem may occur during a window decoding process, in which an error in a preceding window affects the decoding performance of a subsequent window. This is a more serious problem, especially in a low-latency decoding environment, and there is a need for a method that can effectively mitigate error propagation.

In order to solve those problems, a technology to efficiently deactivate check nodes during the decoding process of SC-LDPC and a technology to mitigate error propagation during the window decoding process of SC-LDPC are needed. Accordingly, the present disclosure proposes an improved SC-LDPC decoding technology to overcome the problems of existing technologies and increase the reliability and efficiency of a communication system.

### CITATION LIST

### Patent Literature

Korean Patent Publication No. 10-2022-0097961

### Non-Patent Literature

W. R. Caid and R. W. Means, “Neural network error correcting decoders for block and convolutional codes,” in Proc. IEEE Global Telecommunications Conference and Exhibition (GLOBECOM), 1990, pp. 1028-1031
E. Nachmani, Y. Be'ery, and D. Burshtein, “Learning to decode linear codes using deep learning,” in Proc. 54th Annu. Allerton Conf. Commun., Control, Comput., September 2016, pp. 341-346.

### SUMMARY OF THE INVENTION

An aspect of the present disclosure is to improve decoding performance and reduce complexity and power consumption in a process of decoding SC-LDPC codes. To this end, there is proposed a method of optimizing a weight of an SC-LDPC-based neural network model to efficiently deactivate check node updates, and specifically, there is proposed a method of determining a need for updating each check node based on the trained damping factor. This minimizes unnecessary check node updates and maximizes the efficiency of a decoding process.

In addition, the present disclosure aims to introduce a method of adaptively using a different weight depending on whether an error has occurred in a preceding window, in order to solve an error propagation problem that may occur during a window decoding process. This may effectively mitigate error propagation and stably enhance decoding performance.

The present disclosure ultimately aims to improve the decoding performance and efficiency of SC-LDPC codes simultaneously through such a technical improvement, and to increase the reliability of a communication and storage system.

Meanwhile, technical problems of the present disclosure are not limited to the above-mentioned problems, and other technical problems which are not mentioned herein will be clearly understood by those skilled in the art from the description below.

A method performed by an SC-LDPC-based decoding apparatus operated by a processor according to one embodiment may include an operation of modeling a belief propagation (BP), including sum-product and min-sum variants in this document, message-passing process according to a preset number of iterations of BP calculations in a Tanner graph including check nodes, variable nodes, and messages between each node for SC-LDPC decoding as a layer of a neural network to generate a neural network-based LDPC decoder; an operation of setting a trainable damping factor that adjusts a ratio between a previous message and a current message transmitted from a check node to a variable node to determine whether to activate the check node in repeatedly carrying out BP calculations according to the number of iterations; an operation of training a preset number of neural weight sets for a window, which is a unit in which a decoding process is performed, and separately setting a first weight set, which is used when a decoding result of the previous window is an error occurrence, and a second weight set, which is used when the decoding result of the previous window is normal, to mitigate error propagation between windows; and an operation of training the decoder based on training data including information from a previous window.

Furthermore, the neural network may include an input layer that receives reliability information on each bit of a target codeword which is an error detection object as an input; a first hidden layer that updates a message transmitted from the variable node to the check node; a second hidden layer that updates a message transmitted from the check node to the variable node; and an output layer that outputs improved final reliability information according to the calculation of the hidden layer for each bit of the target codeword.

Furthermore, the neural network may include a hidden layer in which the first hidden layer and the second hidden layer are repeatedly arranged a number of times corresponding to the preset number of iterations.

Furthermore, the input layer may receive information on a log ratio between a probability that each bit constituting the target codeword is 1 and a probability that each bit is 0.

Furthermore, the reliability information may be expressed as Equation 1 below:

$${l}_{v} = log ( \frac{Pr ( {C}_{v} = 1 \vert {y}_{v} )}{Pr ( {C}_{v} = 0 \vert {y}_{v} )} ) \qquad [ Equation 1 ]$$

(Pr(Cᵥ=1|yᵥ) is a probability that a bit of an actual codeword is 1 when a value y received in a v-th bit is given, and Pr(Cᵥ=0|yᵥ) is a probability that the bit of the actual codeword is 0 when the value y received in the v-th bit is given).

Furthermore, the first hidden layer may update a message transmitted from the variable node to the check node based on Equation 2 below:

$${m}_{v \to c}^{( ℓ )} = {\overline{w}}_{v}^{( ℓ )} {m}_{v}^{ch} + {\sum }_{{c}^{′} ∈ N ( v ) \backslash c} {m}_{{c}^{′} \to v}^{( ℓ - 1 )} \qquad [ Equation 2 ]$$

$$( {m}_{v \to c}^{( ℓ )}$$

is a message transmitted from a variable node to a check node during an l-th iteration,

$${m}_{v}^{ch}$$

is a channel output value for a variable node v,

$${\overline{w}}_{v}^{( ℓ )}$$

is a trained weight for the variable node v, N(v) is a set of check nodes connected to the variable node v, and

$${\sum }_{{c}^{′} ∈ N ( v ) \backslash c} {m}_{{c}^{′} \to v}^{( ℓ - 1 )}$$

is a sum of messages sent by check nodes in a previous iteration l−1).

Furthermore, the second hidden layer may update a message transmitted from the check node to the variable node based on Equation 3 below:

$${m}_{c \to v}^{( ℓ )} = {w}_{c \to v}^{( ℓ )} ( {\prod }_{{v}^{′} ∈ N ( c ) \backslash v} sgn ( {m}_{{v}^{′} \to c}^{( ℓ )} ) ) {min}_{{v}^{′} ∈ N ( c ) \backslash v} \vert {m}_{{v}^{′} \to c}^{( ℓ )} \vert \qquad [ Equation 3 ]$$

$$( {m}_{c \to v}^{( ℓ )}$$

is a message transmitted from a check node to a variable node during an l-th iteration,

$${w}_{c \to v}^{( ℓ )}$$

is a trained weight transmitted from a check node to a variable node, N(c) is a set of variable nodes connected to a check node c,

$$\prod sgn ( {m}_{{v}^{′} \to c}^{( ℓ )} )$$

is a product of sign values of all the connected variable nodes, and

$${min}_{{v}^{′} ∈ N ( c ) \backslash v} \vert {m}_{{v}^{′} \to c}^{( ℓ )} \vert$$

is a minimum absolute value of messages received from the connected variable nodes).

Furthermore, the output layer may output the final reliability information based on Equation 4 below:

$${m}_{v}^{o} = {m}_{v}^{ch} + {\sum }_{{c}^{′} ∈ N ( v )} {m}_{{c}^{′} \to v}^{( ℓ )} \qquad [ Equation 4 ]$$

$$( {m}_{v}^{o}$$

is final reliability information of a variable node v, initial channel reliability information of the variable node v, N(v) is a set of check nodes connected to the variable node v, and

$${\sum }_{{c}^{′} ∈ N ( v )} {m}_{{c}^{′} \to v}^{( ℓ )}$$

is a sum of all messages received by the variable node from the check nodes).

Furthermore, an operation of setting the damping factor may include an operation of setting a message transmitted from a check node to a variable node in an iteration order of l-th (l is a natural number) BP calculation based on Equation 5 below:

$${m}_{c \to v}^{( ℓ )} ← {γ}_{C}^{( ℓ )} {m}_{c \to v}^{( ℓ - 1 )} + ( 1 - {γ}_{C}^{( ℓ )} ) {m}_{c \to v}^{( ℓ )} \qquad [ Equation 5 ]$$

(l is an index that specifies an iteration order of BP calculation,

$${m}_{c \to v}^{( ℓ )}$$

is a message transmitted from a check node to a variable node according to an l-th iteration order of BP calculation,

$${m}_{c \to v}^{( ℓ - 1 )}$$

is a message transmitted from a check node to a variable node according to an (l−1)th iteration order of BP calculation,

$${γ}_{C}^{( ℓ )}$$

is a damping factor that determines how much a previous message value is reflected when updating a message, which is a weight trained as a real value greater than or equal to 0 and less than or equal to 1, and

$$( 1 - {γ}_{C}^{( ℓ )} )$$

is a term that determines how much a current message value is reflected when updating a message).

Furthermore, the damping factor may be set so as to allow different values to be trained for each layer and node constituting each iteration order.

Furthermore, the check nodes may be set to be deactivated in an order of importance scores which are calculated based on trained damping factors.

Furthermore, the separately setting operation may include setting some of node groups included in a previous window and some of node groups included in a next window among nodes and edges of the neural network to overlap one another; and setting a first weight set to be applied when a decoding result of the previous window is an error occurrence, and a second weight set to be applied when the decoding result of the previous window is normal to prevent an error occurring in a previous window from being propagated to a next window.

Furthermore, the first weight set may be set to be applied to transmitted messages when calculating BP message of a current window in a case where an error is detected in the reliability information of the codeword in the BP calculation of the previous window.

Furthermore, the second weight set may be set to be applied to transmitted messages when calculating BP message of a current window in a case where no error is detected in the reliability information of the codeword in the BP calculation of the previous window.

Furthermore, the training data may include reliability information on each bit of a codeword decoded from a received vector from a channel, and reliability information on each bit of an original codeword transmitted through the channel as correct data of the codeword.

Furthermore, the reliability information may include information on a log ratio between a probability that each bit constituting the target codeword is 1 and a probability that each bit is 0.

Furthermore, the reliability information may be expressed as Equation 6 below:

$${l}_{v} = log ( \frac{Pr ( {C}_{v} = 1 \vert {y}_{v} )}{Pr ( {C}_{v} = 0 \vert {y}_{v} )} ) \qquad [ Equation 6 ]$$

(Pr(Cᵥ=1|yᵥ) is a probability that a bit of an actual codeword is 1 when a value y received in a v-th bit is given, and Pr(Cᵥ=0|yᵥ) is a probability that the bit of the actual codeword is 0 when the value y received in the v-th bit is given).

Furthermore, the supervised training operation may include an operation of performing supervised training based on a loss function of Equation 6 below that trains all variable nodes within an entire window and a loss function of Equation 7 below that trains a target variable node,

$${L}_{A} = \frac{1}{2} [ 1 - sgn ( {min}_{1 \leq v \leq {WN}_{v}} {m}_{v}^{o} ) ] \qquad [ Equation 7 ]$$

(L_{A} is a loss function that trains total variable nodes, v is an index that specifies a variable node,

$${m}_{v}^{o}$$

is final reliability information of a variable node v, W is a number of variable node positions included in a window, and Nᵥ is a number of variable nodes at each position), and

$${L}_{T} = \frac{1}{2} [ 1 - sgn ( {min}_{1 \leq v \leq {TN}_{v}} {m}_{c}^{o} ) ] \qquad [ Equation 8 ]$$

(L_{T} is a loss function that trains a target variable node, v is an index that specifies a variable node,

$${m}_{v}^{o}$$

is final reliability information of a variable node v, W is a number of variable node positions included in a window, and Nᵥ is a number of variable nodes at each position).

An SC-LDPC-based decoding apparatus according to one embodiment may include a memory including an instruction; and a processor that performs a predetermined operation based on the instruction, wherein the operation of the processor includes an operation of modeling a belief propagation (BP) message transmission process according to a preset number of iterations of BP calculations in a Tanner graph including check nodes, variable nodes, and messages between each node for SC-LDPC decoding as a layer of a neural network to generate a neural network-based LDPC decoder; an operation of setting a damping factor that adjusts a ratio between a previous message and a current message transmitted from a check node to a variable node to determine whether to activate the check node in repeatedly carrying out BP calculations according to the number of iterations; an operation of training a preset number of neural weight sets for a window, which is a unit in which a decoding process is performed, and separately setting a first weight set, which is used when a decoding result of the previous window is an error occurrence, and a second weight set, which is used when the decoding result of the previous window is normal, to mitigate error propagation between windows; and an operation of training the decoder based on training data including information from a previous window.

A computer program stored on a computer-readable recording medium may include, when performed on at least one processor, an instruction that allows the processor to perform: an operation of modeling a belief propagation (BP) message transmission process according to a preset number of iterations of BP calculations in a Tanner graph including check nodes, variable nodes, and messages between each node for SC-LDPC decoding as a layer of a neural network to generate a neural network-based LDPC decoder; an operation of setting a damping factor that adjusts a ratio between a previous message and a current message transmitted from a check node to a variable node to determine whether to activate the check node in repeatedly carrying out BP calculations according to the number of iterations; an operation of training a preset number of neural weight sets for a window, which is a unit in which a decoding process is performed, and separately setting a first weight set, which is used when a decoding result of the previous window is an error occurrence, and a second weight set, which is used when the decoding result of the previous window is normal, to mitigate error propagation between windows; and an operation of training the decoder based on training data including information from a previous window.

The present disclosure optimizes a weight of an SC-LDPC-based neural network model to provide an effect of simultaneously improving decoding performance and efficiency.

Specifically, the present disclosure may reduce unnecessary calculations through efficient deactivation of each check node update based on a damping factor that implements a factor regarding the necessity of updating each check node constituting SC-LDPC as a weight of a neural network model, thereby significantly reducing decoding complexity and power consumption.

In addition, the present disclosure may introduce a method of adaptively using a different weight depending on whether an error has occurred in a preceding window, thereby effectively alleviating error propagation problems that can occur during a window decoding process, and stably maintaining decoding performance.

Through this, the present disclosure may maximize an efficiency of a decoding process and simultaneously improve the reliability and performance of a communication system. Moreover, the present disclosure may expand its applicability in various industrial fields requiring high-speed data transmission and high reliability through such a technical improvement.

Meanwhile, the effects of the present disclosure may not be limited to the above-mentioned effects, and other technical effects which are not mentioned herein will be clearly understood by those skilled in the art from the description below.

### BRIEF DESCRIPTION OF THE DRAWINGS

FIG. 1 is a block diagram of an SC-LDPC-based decoding apparatus according to one embodiment.

FIG. 2 is a flowchart showing steps of operations performed by an SC-LDPC-based decoding apparatus according to one embodiment.

FIG. 3 is an exemplary diagram of a Tanner graph according to one embodiment.

FIG. 4 is an exemplary diagram of implementing the Tanner graph of FIG. 3 using a neural network-based decoder.

FIG. 5 is an exemplary diagram of an operation that sets a window in an SC-LDPC decoding process according to one embodiment.

FIG. 6 is a conceptual diagram of a weight adjustment mechanism that mitigates inter-window error propagation according to one embodiment.

FIG. 7 is exemplary diagram of a heat map showing a weight distribution in a window decoding process for each position of a check node according to one embodiment.

FIG. 8 is an exemplary diagram of a graph comparing error propagation probabilities for various decoding techniques according to one embodiment.

FIG. 9 is an exemplary diagram of a graph comparing average block error rate performances for various decoding techniques according to one embodiment.

### DETAILED DESCRIPTION OF THE PREFERRED EMBODIMENT

The details of the objects and technical configurations of the present disclosure and operational effects thereof will be more clearly understood from the following detailed description based on the accompanying drawings appended hereto. Hereinafter, embodiments according to the present disclosure will be described in detail with reference to the accompanying drawings.

Embodiments disclosed herein should not be interpreted as limiting or used to limit the scope of the present disclosure. It is apparent for those skilled in the art that a description including embodiments herein has various applications. Therefore, any embodiments described in the detailed description of the present disclosure are illustrative for better understanding of the present disclosure and are not intended to limit the scope of the present disclosure to the embodiments.

Functional blocks illustrated in the drawings and described hereunder are only examples of possible implementations. In other implementations, other functional blocks may be used without departing from the concept and scope of the detailed description. Furthermore, one or more functional blocks of the present disclosure are illustrated as separate blocks, but one or more of the functional blocks of the present disclosure may be a combination of various hardware and software elements that execute the same function.

In addition, an expression that some elements are “included” is an expression of an “open type”, and the expression simply denotes that the corresponding elements are present, but should not be construed as excluding additional elements.

Moreover, in case where it is mentioned that one element is “connected” or “coupled” to the other element, it should be understood that one element may be directly connected to the other element, but another element may be present therebetween.

Hereinafter, various embodiments of the present disclosure will be described with reference to the accompanying drawings. However, it should be understood that the embodiments are not intended to limit the present disclosure to specific embodiments, and include various modifications, equivalents, and/or alternatives of the embodiments of the present disclosure.

The present disclosure proposes an SC-LDPC-based decoding apparatus 100 implementing a technology that optimizes a weight of an SC-LDPC-based neural network model to efficiently deactivate a check node during a decoding process of a spatially coupled low-density parity-check (hereinafter, ‘SC-LDPC’) code and to solve an error propagation problem that may occur during a window decoding process of SC-LDPC.

Hereinafter, a configuration of the SC-LDPC-based decoding apparatus 100 of the present disclosure and an operation of each components will be examined.

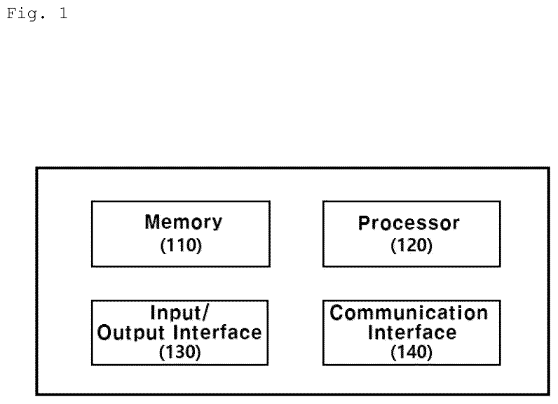

FIG. 1 is a configuration diagram of the SC-LDPC-based decoding apparatus 100 (hereinafter, referred to as an ‘apparatus 100’) according to one embodiment.

Referring to FIG. 1, the apparatus 100 according to one embodiment may each include a memory 110, a processor 120, an input/output interface 130, and a communication interface 140.

The memory 110 may store data acquired from an external apparatus or data generated by itself. The memory 110 may store instructions that can perform an operation of the processor 120. For example, the memory 110 may store a neural network-based LDPC decoder, and the like, which will be described later.

The processor 120 is a calculation apparatus that controls an overall operation. The processor 120 may execute instructions stored in the memory 110. The operation of the apparatus 100 according to an embodiment of the disclosure may be understood as an operation performed by the processor 120.

The input/output interface 130 may include a hardware interface or software interface that inputs and outputs information.

The communication interface 140 allows information to be transmitted and received through a communication network. To this end, the communication interface 140 may include a wireless communication module or a wired communication module.

The apparatus 100 may be implemented as various types of apparatuses capable of performing calculations through the processor 120 and transmitting and receiving information through a network. For example, it may be implemented in a form of a server, a computer device, a portable communication apparatus, a smart phone, a portable multimedia apparatus, a laptop, a tablet PC, and the like, but is not limited to those examples.

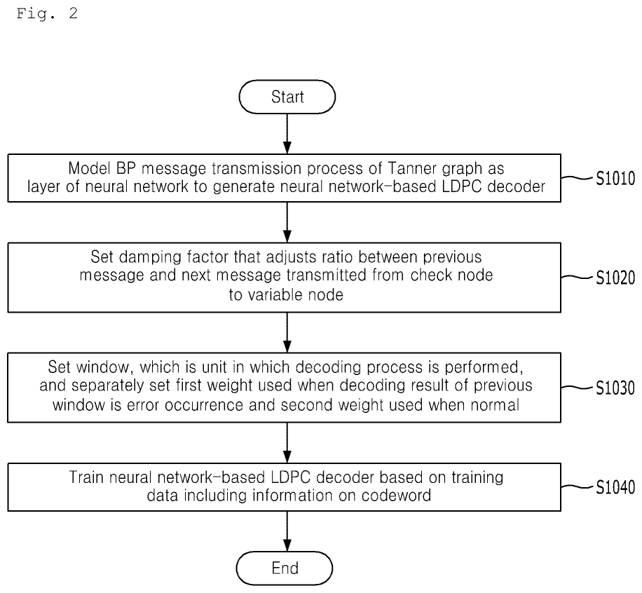

FIG. 2 is a flowchart of operations performed by the apparatus 100 according to one embodiment. The operation of the apparatus 100 according to an embodiment in FIG. 2 may be understood as an operation performed by the processor 120.

Each step disclosed in FIG. 2 is only a preferred embodiment in achieving the objectives of the present disclosure, and some steps may be added thereto or deleted therefrom as needed, and any one step may be included in another step to be performed. The order of respective operations disclosed in FIG. 2 is only arranged for convenience of understanding, and such an order is not limited to a time series order, and the order may be changed and operated differently depending on the designer's choice.

Referring to FIG. 2, in step S1010, the apparatus 100 may generate a neural network-based LDPC decoder that models a belief propagation (BP) message transmission process for SC-LDPC decoding as a layer of a neural network.

Here, SC-LDPC is an LDPC code that has a structure that temporally or spatially extends connections between variable nodes (VNs) and check nodes (CNs) to improve the performance of existing LDPC codes. While general LDPC codes perform decoding using an entire parity check matrix, SC-LDPC has a characteristic of performing incremental decoding in units of windows, which may improve decoding performance while reducing complexity.

Decoding of SC-LDPC codes is performed by exchanging messages between check nodes and variable nodes in a Tanner graph, and a window decoding technique is used in this process. Window decoding, which is a method that allows low-latency decoding of SC-LDPC codes, performs decoding within each window while sequentially moving windows.

The structure of SC-LDPC may be expressed as a Tanner graph, which is a bipartite graph that connects a variable node and a check node of an LDPC code, wherein the variable node represents each bit (or log-likelihood ratio) of a codeword, and the check node serves to force the corresponding bits to satisfy a specific parity condition.

In the Tanner graph, variable nodes and check nodes are connected by edges, and a belief propagation (BP) algorithm is performed through the connection relationships. A BP message is reliability information (log-likelihood ratio, LLR) that is repeatedly transmitted between a variable node and a check node during an LDPC decoding process, which is repeatedly performed such that initially the variable node transmits a message to the check node based on a codeword received from a channel, and then the check node combines information on the connected variable nodes to generate a new message and then transmits it back to the variable node.

Here, the codeword refers to a bit string generated through channel coding to protect data and enable error correction on the transmitting side. On the transmitting side, a specific LDPC encoding process is applied to the original data (message bits) to generate a codeword, which is modulated at the transmitter and then transmitted through a wireless or wired channel. Since noise or interference may occur in a process of transmitting through the channel, the receiving side performs a process of restoring the original codeword based on the received signal. The apparatus 100 may utilize a BP algorithm based on a Tanner graph in an SC-LDPC decoding process to convert a probability that each bit of the codeword is 1 and a probability that each bit is 0 in the received signal into a log ratio as in Equation 1 below, and then restore the original data through repeated message transmission.

$${l}_{v} = log ( \frac{Pr ( {C}_{v} = 1 \vert {y}_{v} )}{Pr ( {C}_{v} = 0 \vert {y}_{v} )} ) \qquad [ Equation 1 ]$$

(Pr(Cᵥ=1|yᵥ) is a probability that a bit of an actual codeword is 1 when a value y received in a v-th bit is given, and Pr(Cᵥ=0|yᵥ) is a probability that the bit of the actual codeword is 0 when the value y received in the v-th bit is given).

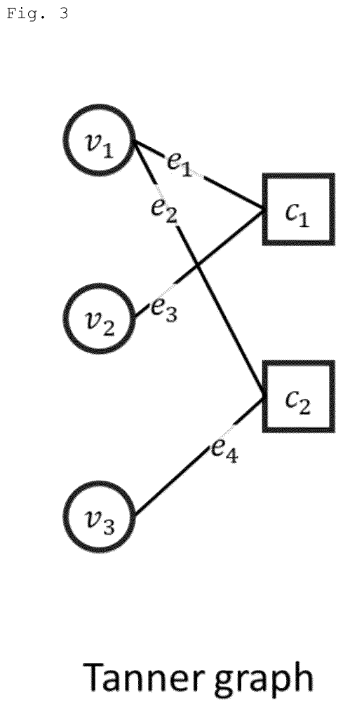

FIG. 3 is an exemplary diagram of a Tanner graph according to one embodiment.

Referring to FIG. 3, the Tanner graph, which is a model that expresses a structure of an SC-LDPC code in a form of a graph, represents a structure in which variable nodes v1, v2, v3 and check nodes c1, c2 are connected in a form of a binary graph. A variable node represents each bit (or log-likelihood ratio) of a codeword, and a check node serves to force the corresponding variable nodes to satisfy a specific parity check condition. Additionally, variable nodes and check nodes are connected via edges e1, e2, e3, and each edge represents a BP message exchanged between the variable node and the check node. In the Tanner graph, a BP message transmission algorithm is performed, and variable nodes and check nodes carry out decoding while repeatedly exchanging reliability information. A process in which the variable node transmits an initial LLR value received from the channel to the check node, and the check node utilizes information on the connected variable nodes to calculate a new message and then transmits it back to the variable node is repeated performed. This increases the probability that each bit of the codeword is to be decoded correctly.

The apparatus 100 may model a BP message transmission process according to a preset number of iterations in a Tanner graph including check nodes, variable nodes, and messages between each node for SC-LDPC decoding as a layer of a neural network to generate a neural network-based LDPC decoder. If the BP algorithm is converted into a neural network model, each layer of the neural network may correspond to an iteration of the BP algorithm, and train an optimal message transmission method through training.

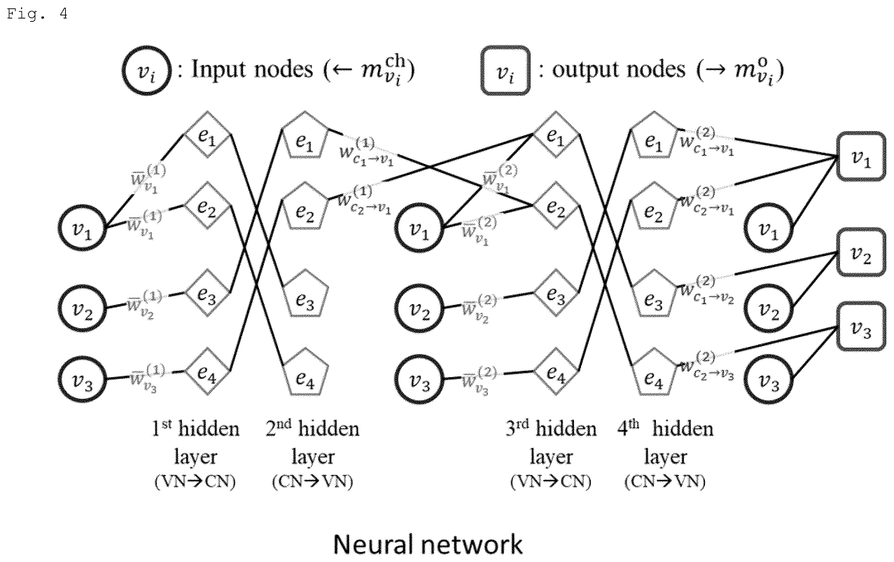

FIG. 4 is an exemplary diagram of implementing the Tanner graph of FIG. 3 using a neural network-based decoder.

Referring to FIG. 4, it can be confirmed that a message transmission process between a variable node and a check node in a Tanner graph has been modeled by converting it into a layer structure of the neural network. This allows the LDPC decoding process to be optimized through neural network training.

Leftmost circular nodes in FIG. 4, which are input nodes, include initial reliability values received from the channel, and receive information on a log ratio between a probability that each bit constituting a target codeword is 1 and a probability that each bit is 0. Rightmost nodes with a square border in FIG. 4, which are output nodes, output the decoded final reliability information. Additionally, a node that specifies a message to be transmitted from a variable node to a check node and a node that specifies a message to be transmitted from a check node to a variable node may form a hidden layer as follows.

In this case, an internal structure of the neural network may be composed of multiple hidden layers, and messages between variable nodes and check nodes may be implemented as nodes and layers according to a preset number of iterations of the BP algorithm.

As an example, FIG. 4 may include an input layer that receives log ratio information between a probability that each bit constituting a target codeword which is an error detection object is 1 and a probability that each bit is 0, a first hidden layer (1st hidden layer, 3rd hidden layer, VN->CN) that updates a message transmitted from a variable node to a check node, a second hidden layer (2nd hidden layer, 4th hidden layer, CN->VN) that updates a message transmitted from a check node to a variable node, and an output layer that outputs improved final reliability information according to the calculation of the hidden layer for each bit of the target codeword. In this case, the first hidden layer and the second hidden layer may be repeatedly arranged a number of times corresponding to a preset number of iterations of BP calculations. That is, in FIG. 4, there are four hidden layers, which reflects a structure of performing two iterations of the BP algorithm.

As an example, the first hidden layer may update a message transmitted from the variable node to the check node based on Equation 2.

$${m}_{v \to c}^{( ℓ )} = {w}_{v}^{( ℓ )} {m}_{v}^{ch} + {\sum }_{{c}^{′} ∈ N ( v ) \backslash c} {m}_{{c}^{′} \to v}^{( ℓ - 1 )} \qquad [ Equation 2 ]$$

$$( {m}_{v \to c}^{( ℓ )}$$

is a message transmitted from a variable node to a check node during an l-th iteration,

$${m}_{v}^{ch}$$

is a channel output value for a variable node v,

$${\overline{w}}_{v}^{( ℓ )}$$

is a trained weight for the variable node v, N(v) is a set of check nodes connected to the variable node v, and

$${\sum }_{{c}^{′} ∈ N ( v ) \backslash c} {m}_{{c}^{′} \to v}^{( ℓ - 1 )}$$

is a sum of messages sent by check nodes in a previous iteration l−1).

As an example, the second hidden layer may update a message transmitted from the check node to the variable node based on Equation 3.

$${m}_{c \to v}^{( ℓ )} = {w}_{c \to v}^{( ℓ )} ( {\prod }_{{v}^{′} ∈ N ( c ) \backslash v} sgn ( {m}_{{v}^{′} \to c}^{( ℓ )} ) ) {min}_{{v}^{′} ∈ N ( c ) \backslash v} \vert {m}_{{v}^{′} \to c}^{( ℓ )} \vert$$

$$( {m}_{c \to v}^{( ℓ )}$$

is a message transmitted from a check node to a variable node during an l-th iteration,

$${w}_{c \to v}^{( ℓ )}$$

is a trained weight transmitted from a check node to a variable node, N(c) is a set of variable nodes connected to a check node c,

$$\prod sgn ( {m}_{{v}^{′} \to c}^{( ℓ )} )$$

is a product of sign values of all the connected variable nodes, and

$${min}_{{v}^{′} ∈ N ( c ) \backslash v} \vert {m}_{{v}^{′} \to c}^{( ℓ )} \vert$$

is a minimum absolute value of messages received from the connected variable nodes).

As an example, the output layer may output final reliability information that improves the reliability information of the initially input codeword based on Equation 4 below.

$${m}_{v}^{o} = {m}_{v}^{ch} + {\sum }_{{c}^{′} ∈ N ( v )} {m}_{{c}^{′} \to v}^{( ℓ )} \qquad [ Equation 4 ]$$

$$( {m}_{v}^{o}$$

is final reliability information of a variable node v, initial channel reliability information of the variable node v, N(v) is a set of check nodes connected to the variable node v, and

$${\sum }_{{c}^{′} ∈ N ( v )} {m}_{{c}^{′} \to v}^{( ℓ )}$$

is a sum of all messages received by the variable node from the check nodes).

In FIG. 4, weights expressed in red letters are weights applied to messages transmitted from variable nodes to check nodes, and weights expressed in blue letters are weights applied to messages transmitted from check nodes to variable nodes. The apparatus 100 may allow the neural network to adjust an optimal weight through training so as to improve the performance of the BP algorithm.

In step S1020, the apparatus 100 may set a damping factor that adjusts a ratio between a previous message and a current message transmitted from a check node to a variable node to determine whether to activate the check node in repeatedly carrying out BP calculations according to a preset number of iterations of BP calculation.

As an example, the apparatus 100 may set a message to be transmitted from a check node to a variable node in an iteration order of l-th (l is a natural number) BP calculation based on Equation 5 below.

$${m}_{c \to v}^{( ℓ )} ← {γ}_{C}^{( ℓ )} {m}_{c \to v}^{( ℓ - 1 )} + ( 1 - {γ}_{C}^{( ℓ )} ) {m}_{c \to v}^{( ℓ )} \qquad [ Equation 5 ]$$

(l is an index that specifies an iteration order of BP calculation,

$${m}_{c \to v}^{( ℓ )}$$

is a message transmitted from a check node to a variable node according to an l-th iteration order of BP calculation,

$${m}_{c \to v}^{( ℓ - 1 )}$$

is a message transmitted from a check node to a variable node according to an (l−1)th iteration order of BP calculation,

$${γ}_{C}^{( ℓ )}$$

is a damping factor that determines how much a previous message value is reflected when updating a message, which is a weight trained as a real value greater than or equal to 0 and less than or equal to 1, and

$$( 1 - {γ}_{C}^{( ℓ )} )$$

is a term that determines how much a current message value is reflected when updating a message).

In this case, the apparatus 100 may set a damping factor so as to allow different weights to be trained for each layer and node constituting each iteration order. Accordingly, when training to be described later is completed, the check nodes included in the neural network may be deactivated in an order of importance scores which are calculated based on trained damping factors.

In step S1030, the apparatus 100 may divide nodes and edges of the neural network into a preset number of groups to set a window, which is a unit in which a decoding process is performed, and separately set a first weight set, which is used when a decoding result of the previous window is an error occurrence, and a second weight set, which is used when the decoding result of the previous window is normal, to mitigate error propagation between windows.

A window will be described as follows based on a structure of SC-LDPC.

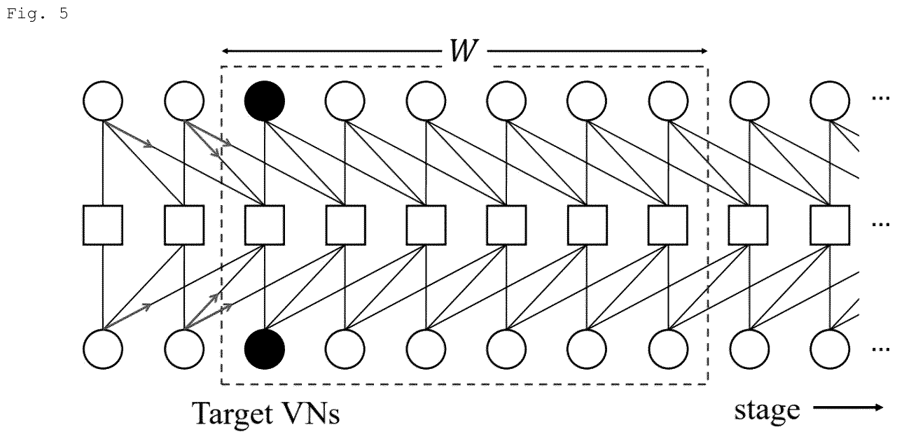

FIG. 5 is an exemplary diagram of an operation that sets a window in an SC-LDPC decoding process according to one embodiment.

Referring to FIG. 5, a structure of performing decoding in units of windows is shown in an SC-LDPC decoding process based on a Tanner graph. In FIG. 5, a window size W is set as a factor that specifies a number of variable nodes and check nodes in which decoding is performed. Each window includes a predetermined number of variable nodes and check nodes on a Tanner graph, and a BP algorithm may be performed in units of windows.

In FIG. 5, a circular node represents a variable node, and a square node represents a check node. Each variable node is connected to a check node, and messages are exchanged through edges to perform repeated reliability update calculations. In particular, some variable nodes (black nodes) marked as target variable nodes (VNs) are variable nodes that serve as criteria for error detection and decoding performance evaluation during the decoding process. The target variable node may be used to select specific variable nodes within a window so as to perform neural network training and weight updates centered on the decoding performance of the nodes. Additionally, red arrows represent messages propagating from an adjacent window, which visually represents a structure in which a decoding result of a previous window affects a decoding process of a next window.

Subsequently, in this embodiment, a window specified in a neural network is a ‘region’ that is an object of decoding at a specific point in time. The window may be set based on the unit of connection relationship between variable nodes and check nodes in the foregoing Tanner graph, and decoding calculation may be carried out in the unit including the variable nodes and check nodes set as the window. Additionally, the apparatus 100 may be configured so as to allow some nodes included in the previous window and some nodes included in the next window to overlap one another, thereby allowing a continuous decoding process. For example, the apparatus 100 may move a window that specifies a partial region of codes in a predetermined direction, and sequentially carry out decoding in units of windows.

As an example, in order to prevent an error occurring in the previous window from propagating to the next window, the apparatus 100 may separately set a weight of the next window so as to be trained based on the situation according to whether an error has occurred in the previous window. For example, the apparatus 100 may dynamically adjust a weight applied in the next window according to a decoding result of the previous window, thereby mitigating error propagation and optimizing decoding performance.

As an example, a first weight set, which is a weight applied when transmitting BP calculation information of the window to the next window in a case where an error is detected in the reliability information of a codeword in the BP calculation of the previous window, may be applied to transmitted messages. This allows to prevent decoding errors from being accumulated by adjusting the reliability information in which an error has occurred not to be excessively reflected in the next window.

As an example, a second weight set, which is a weight used when transmitting BP calculation information of the previous window to the next window in a case where an error is not detected in the reliability information of a codeword in the BP calculation of the previous window, may be applied to transmitted messages. In this case, normally decoded information is maintained as it is, so that reliability may be maintained during continuous window-based decoding processes.

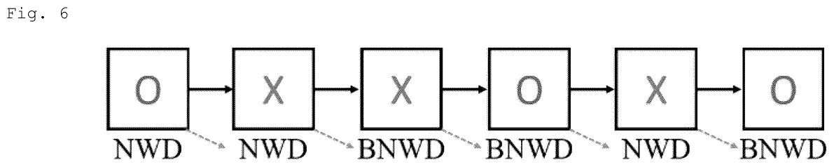

FIG. 6 is a conceptual diagram of a weight adjustment mechanism that mitigates inter-window error propagation according to one embodiment.

Referring to FIG. 6, each rectangular block represents an individual window, and the color and code thereinside indicate a state of the decoded codeword in the window. That is, a blue O means that decoding has been performed normally in the window, and a red X means that an error has occurred in the window. In addition, a black arrow between windows indicates a calculation order for each window, and since a result of a previous window affects decoding of a next window, it indicates that training is performed by applying a second weight set (neural window decoder, NWD) when there is no error in the previous window, and applying a first weight set (breakwater NWD, BNWD) when an error has occurred in the previous window to prevent a window in which an error has occurred from negatively affecting the decoding performance of the next window. Through this, the present disclosure may obtain an effect of preventing continuous error propagation in an actual SC-LDPC decoding process, and improving decoding performance.

In step S1040, the apparatus 100 may train a neural network-based LDPC decoder based on training data including information on a codeword. To this end, the apparatus 100 may train the weight by comparing the received reliability information and the original codeword information based on the weight setting of S1020 or S1030 for training the neural network according to the design of S1010.

As an example, training data may include reliability information on each bit of a codeword decoded from a received vector from a channel, and reliability information on each bit of an original codeword transmitted through the channel as correct data of the codeword. That is, the received reliability information may be compared with the bit values of the actual original codeword to train the neural network, thereby forming an optimal BP message transmission structure.

In this case, the received signal may include information on a log ratio between a probability that each bit of the codeword is 1 and a probability that each bit is 0, and this may be expressed as Equation 5 below.

$${l}_{v} = log ( \frac{Pr ( {C}_{v} = 1 \vert {y}_{v} )}{Pr ( {C}_{v} = 0 \vert {y}_{v} )} ) \qquad [ Equation 5 ]$$

(Pr(Cᵥ=1|yᵥ) is a probability that a bit of an actual codeword is 1 when a value y received in a v-th bit is given, and Pr(Cᵥ=0|yᵥ) is a probability that the bit of the actual codeword is 0 when the value y received in the v-th bit is given).

Accordingly, the apparatus 100 may perform supervised training for a neural network-based LDPC decoder based on a loss function of Equation 6 below that trains all variable nodes within an entire window and a loss function of Equation 7 below that trains a target variable node.

$${L}_{A} = \frac{1}{2} [ 1 - sgn ( {min}_{1 \leq v \leq {WN}_{v}} {m}_{v}^{o} ) ] \qquad [ Equation 6 ]$$

(L_{A} is a loss function that trains total variable nodes, v is an index that specifies a variable node,

$${m}_{v}^{0}$$

is final reliability information of a variable node v, W is a number of variable node positions included in a window, and Nᵥ is a number of variable nodes at each position).

In Equation 6, a ‘position’ is a unit of space that is skipped when moving from a window at a certain point in time to a window at a next point in time. Referring again to FIG. 5, a ‘position’ corresponds to one vertical column in the drawing. The movement of the window is carried out by decoding black variable nodes and then moving one space to the right to move to the next window. According to an example of FIG. 5, W=6, and Nᵥ=2 in Equation 6.

The loss function according to Equation 6, which is a loss function configured to optimize a neural network at all variable nodes within an entire window, may optimize a message transmission process between a variable node and a check node to minimize a decoding error.

$${L}_{T} = \frac{1}{2} [ 1 - sgn ( {min}_{1 \leq v \leq {TN}_{v}} {m}_{v}^{o} ) ] \qquad [ Equation 7 ]$$

(L_{T} is a loss function that trains a target variable node, v is an index that specifies a variable node,

$${m}_{v}^{o}$$

is final reliability information of a variable node v, W is a number of variable node positions included in a window, and Nᵥ is a number of variable nodes at each position).

The loss function of Equation 7, which is a loss function that sets a specific target variable node as a training object to intensively reduce an error occurring in a target node, may effectively mitigate error propagation occurring in a continuous window decoding process.

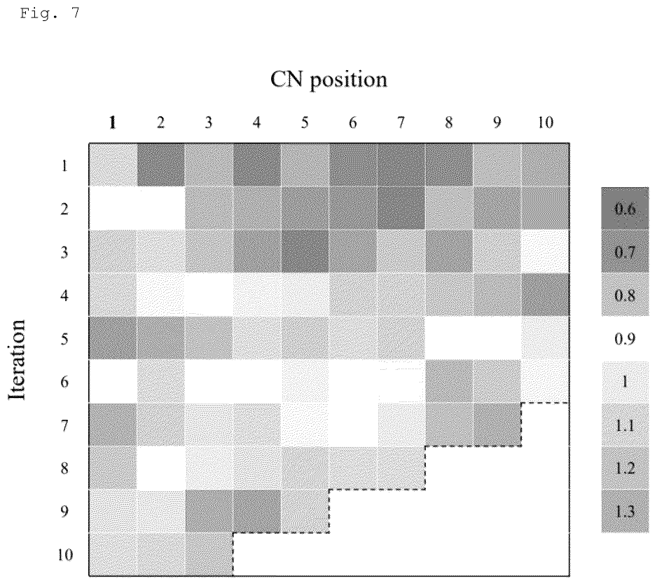

In this embodiment, neural network training may be performed in a supervised training manner, and as the loss function is trained in a direction that minimizes the decoding error, the foregoing damping factor, first weight set, and second weight set are optimized. Accordingly, the present disclosure may minimize unnecessary power consumption by efficiently deactivating check nodes as shown in the experimental results of FIGS. 7 to 9, and may alleviate error propagation and improve decoding performance in a window-based SC-LDPC decoding process.

FIG. 7 is exemplary diagram of a heat map showing a weight distribution in a window decoding process for each position of a check node according to one embodiment.

A vertical axis in FIG. 7 represents a number of iterations, a horizontal axis represents a position of a check node, and a color of each cell represents a weight value.

Referring to FIG. 7, low weights (red) are distributed overall in initial iterations, but a pattern in which weights increase (blue) in specific check nodes is shown as the number of iterations increases. In particular, a dotted line indicates that a method of adjusting weights depending on whether an error occurred in a previous window has been trained.

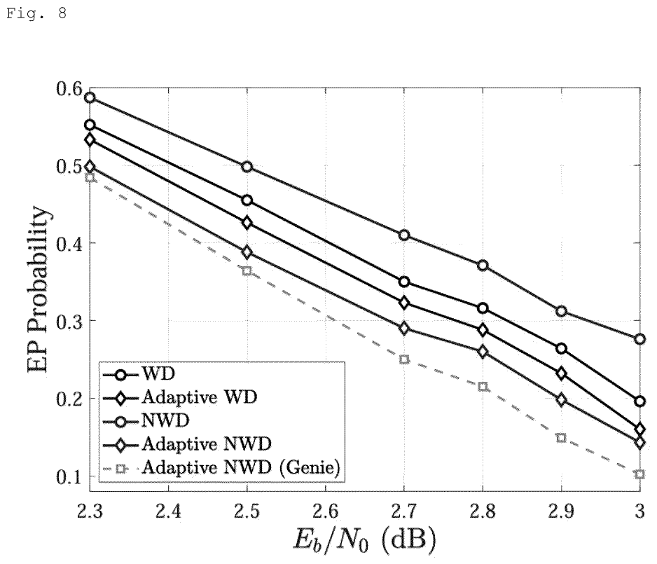

FIG. 8 is an exemplary diagram of a graph comparing error propagation probabilities for various decoding techniques according to one embodiment.

A horizontal axis in FIG. 8 represents a signal-to-noise ratio, and a vertical axis represents an error propagation probability, wherein a performance difference according to the error propagation probability is compared between the existing technology and the present disclosure.

Referring to FIG. 8, the present disclosure (adaptive NWD) records a lowest EP probability, which shows that the neural network can provide optimal error mitigation performance in an ideal environment. Through this, it can be confirmed that the method of the present disclosure can effectively suppress error propagation in SC-LDPC decoding and improve decoding performance than the existing WD and NWD methods.

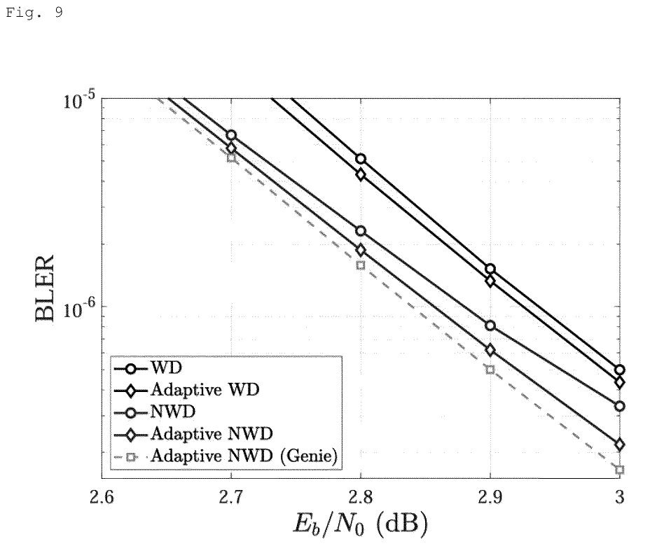

FIG. 9 is an exemplary diagram of a graph comparing average block error rate performances for various decoding techniques according to one embodiment.

A horizontal axis in FIG. 9 represents a signal-to-noise ratio, and a vertical axis represents an average block error rate, wherein a performance difference according to the average block error rate is compared between the existing technology and the present disclosure.

Referring to FIG. 9, it can be confirmed that the present disclosure (adaptive NWD) maintains a lower block error rate than the existing WD and NWD methods, which means that the present disclosure can effectively suppress error propagation in a window-based decoding process to improve decoding performance. Therefore, it can be confirmed that the present disclosure can improve SC-LDPC decoding performance by dynamically adjusting weights through neural network training while maintaining a lower error rate than the existing method.

According to the foregoing embodiment, the present disclosure optimizes a weight of an SC-LDPC-based neural network model to provide an effect of simultaneously improving decoding performance and efficiency.

Specifically, the present disclosure may reduce unnecessary calculations through efficient deactivation of each check node update based on a damping factor that implements a factor regarding the necessity of updating each check node constituting SC-LDPC as a weight of a neural network model, thereby significantly reducing decoding complexity and power consumption.

In addition, the present disclosure may introduce a method of adaptively using a different weight depending on whether an error has occurred in a preceding window, thereby effectively alleviating error propagation problems that can occur during a window decoding process, and stably maintaining decoding performance.

Through this, the present disclosure may maximize an efficiency of a decoding process and simultaneously improve the reliability and performance of a communication system. Moreover, the present disclosure may expand its applicability in various industrial fields requiring high-speed data transmission and high reliability through such a technical improvement.

It should be understood that various embodiments of the disclosure and terms used herein are not intended to limit the technical features described in the disclosure to specific embodiments, and include various modifications, equivalents, or alternatives of the embodiments. With regard to the description of the drawings, similar reference numerals may be used for similar or related elements. A singular form of a noun corresponding to an item may include one or more of the things, unless the relevant context clearly indicates otherwise.

In the disclosure, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. Terms such as “1st”, “2nd”, or “first” and “second” may be used merely to differentiate a corresponding element from another, and do not limit the elements in any other aspect (e.g., importance or order). When an element (e.g., a first element) is referred to as being “coupled” or “connected” to another element (e.g., a second element), with or without the term “functionally” or “communicatively,” it means that the element may be connected to the other element directly (e.g., in a wired manner), in a wireless manner, or through a third element.

The term “module” as used in the disclosure may include a unit implemented in hardware, software or firmware, and may be used interchangeably with terms such as logic, logic block, component, or circuit. A module may be an integrally configured component or a minimum unit of the component that performs one or more functions or a part thereof. For example, according to one embodiment, the module may be implemented in a form of an application-specific integrated circuit (ASIC).

Various embodiments of the disclosure may be implemented as software (e.g., a program) including one or more instructions stored in a storage medium (e.g., a memory) that is readable by a device (e.g., an electronic apparatus). The storage medium may include a random access memory (RAM), a memory buffer, a hard drive, a database, an erasable programmable read-only memory (EPROM), an electrically erasable read-only memory (EEPROM), a read-only memory (ROM), and/or the like.

In addition, a processor in embodiments of the disclosure may retrieve at least one instruction from among one or more instructions stored from a storage medium and execute the retrieved instruction. This allows the device to operate to perform at least one function according to the retrieved at least one instruction. The one or more instructions may include a code generated by a compiler or a code executable by an interpreter. The processor may be a general purpose processor, a field programmable gate array (FPGA), an application specific integrated circuit (ASIC), a digital signal processor (DSP), and/or the like.

The device-readable storage medium may be provided in a form of a non-transitory storage medium. Here, the term ‘non-transitory’ simply means that the storage medium is a tangible apparatus and does not include a signal (e.g. electromagnetic waves), and this term does not differentiate between a case where data is stored semi-permanently and a case where the data is temporarily on the storage medium.

A method according to various embodiments disclosed in the disclosure may be included and provided in a computer program product. The computer program product may be traded as a commodity between a seller and a buyer. The computer program product may be distributed in a form of a device-readable storage medium (e.g., compact disc read only memory (CD-ROM)), or be distributed (e.g., downloaded or uploaded) online via an application store (e.g., PlayStore) or directly between two user apparatuses (e.g., smartphones). In the case of online distribution, at least part of the computer program product may be at least temporarily stored or temporarily generated in the device-readable storage medium, such as a manufacturer's server, a server of an application store, or a server's memory.

According to various embodiments, each element (e.g., a module or a program) of the above-described elements may include a single entity or a plurality of entities. According to various embodiments, one or more of the aforementioned elements or operations may be omitted, or one or more other elements or operations may be added. Alternatively or additionally, the plurality of elements (e.g., modules or programs) may be integrated into a single element. In such a case, the integrated element may perform one or more functions of each of the plurality of elements in the same or similar manner to those performed by a corresponding one of the plurality of elements prior to the integration. According to various embodiments, operations performed by a module, a program or another element may be executed sequentially, in parallel, repeatedly, or heuristically, or one or more of the operations may be executed in a different order, omitted, or one or more other operations may be added.

### DESCRIPTION OF SYMBOLS

100: Apparatus
110: Memory
120: Processor
130: Input/output interface
140: Communication interface

What is claimed is:

1. A method performed by an SC-LDPC-based decoding apparatus operated by a processor, the method comprising:
an operation of modeling a belief propagation (BP) message transmission process according to a preset number of iterations of BP calculations in a Tanner graph including check nodes, variable nodes, and messages between each node for SC-LDPC decoding as a layer of a neural network to generate a neural network-based LDPC decoder;
an operation of setting a damping factor that adjusts a ratio between a previous message and a current message transmitted from a check node to a variable node to determine whether to activate the check node in repeatedly carrying out BP calculations according to the number of iterations;
an operation of training a preset number of neural weight sets for a window, which is a unit in which a decoding process is performed, and separately setting a first weight set, which is used when a decoding result of the previous window is an error occurrence, and a second weight set, which is used when the decoding result of the previous window is normal, to mitigate error propagation between windows; and
an operation of training the decoder based on training data including information from a previous window.

2. The method of claim 1, wherein the neural network comprises:
an input layer that receives reliability information on each bit of a target codeword which is an error detection object as an input;
a first hidden layer that updates a message transmitted from the variable node to the check node;
a second hidden layer that updates a message transmitted from the check node to the variable node; and
an output layer that outputs improved final reliability information according to the calculation of the hidden layer for each bit of the target codeword.

3. The method of claim 2, wherein the neural network comprises:
a hidden layer in which the first hidden layer and the second hidden layer are repeatedly arranged a number of times corresponding to the preset number of iterations.

4. The method of claim 3, wherein the input layer receives information on a log ratio between a probability that each bit constituting the target codeword is 1 and a probability that each bit is 0.

5. The method of claim 4, wherein the reliability information is expressed as Equation 1 below:
$${l}_{v} = log ( \frac{Pr ( {C}_{v} = 1 \vert {y}_{v} )}{Pr ( {C}_{v} = 0 \vert {y}_{v} )} ) \qquad [ Equation 8 ]$$
(Pr(Cᵥ=1|yᵥ) is a probability that a bit of an actual codeword is 1 when a value y received in a v-th bit is given, and Pr(Cᵥ=0|yᵥ) is a probability that the bit of the actual codeword is 0 when the value y received in the v-th bit is given).

6. The method of claim 3, wherein the first hidden layer updates a message transmitted from the variable node to the check node based on Equation 2 below:
$${m}_{v \to c}^{( ℓ )} = {\overline{w}}_{v}^{( ℓ )} {m}_{v}^{ch} + {\sum }_{{c}^{′} ∈ N ( v ) \backslash c} {m}_{v}^{( ℓ - 1 )} \qquad [ Equation 2 ]$$
$$( {m}_{v \to c}^{( ℓ )}$$
is a message transmitted from a variable node to a check node during an l-th iteration,
$${m}_{v}^{ch}$$
is a channel output value for a variable node v,
$${\overline{w}}_{v}^{( ℓ )}$$
is a trained weight for the variable node v, N(v) is a set of check nodes connected to the variable node v, and
$${\sum }_{{c}^{′} ∈ N ( v ) \backslash c} {m}_{{c}^{′} \to v}^{( ℓ - 1 )}$$
is a sum of messages sent by check nodes in a previous iteration l−1).

7. The method of claim 3, wherein the second hidden layer updates a message transmitted from the check node to the variable node based on Equation 3 below:
$${m}_{c \to v}^{( ℓ )} =$$
$$( {m}_{c \to v}^{( ℓ )} = {w}_{c \to v}^{( ℓ )} ( {\prod }_{{v}^{′} ∈ N ( c ) \backslash v} sgn ( {m}_{{v}^{′} \to c}^{( ℓ )} ) ) {min}_{{v}^{′} ∈ N ( c ) \backslash v} \vert {m}_{{v}^{′} \to c}^{( ℓ )} \vert \qquad [ Equation 3 ]$$
is a message transmitted from a check node to a variable node during an l-th iteration,
$${w}_{c \to v}^{( ℓ )}$$
is a trained weight transmitted from a check node to a variable node, N(c) is a set of variable nodes connected to a check node c,
$$\prod sgn ( {m}_{{v}^{′} \to c}^{( ℓ )} )$$
is a product of sign values of all the connected variable nodes, and
$${min}_{{v}^{′} ∈ N ( c ) \backslash v} \vert {m}_{{v}^{′} \to c}^{( ℓ )} \vert$$
is a minimum absolute value of messages received from the connected variable nodes).

8. The method of claim 3, wherein the output layer outputs the final reliability information based on Equation 4 below:
$${m}_{v}^{o} = {m}_{v}^{ch} + {\sum }_{{c}^{′} ∈ N ( v )} {m}_{{c}^{′} \to v}^{( ℓ )} \qquad [ Equation 4 ]$$
$$( {m}_{v}^{o}$$
is final reliability information of a variable node v, initial channel reliability information of the variable node v, N(v) is a set of check nodes connected to the variable node v, and
$${\sum }_{{c}^{′} ∈ N ( v )} {m}_{{c}^{′} \to v}^{( ℓ )}$$
is a sum of all messages received by the variable node from the check nodes).

9. The method of claim 1, wherein an operation of setting the damping factor comprises:
an operation of setting a message transmitted from a check node to a variable node in an iteration order of l-th (l is a natural number) BP calculation based on Equation 5 below:
$${m}_{c \to v}^{( ℓ )} ← {γ}_{C}^{( ℓ )} {m}_{c \to v}^{( ℓ - 1 )} + ( 1 - {γ}_{C}^{( ℓ )} ) {m}_{c \to v}^{( ℓ )} \qquad [ Equation 5 ]$$
(l is an index that specifies an iteration order of BP calculation,
$${m}_{c \to v}^{( ℓ )}$$
is a message transmitted from a check node to a variable node according to an l-th iteration order of BP calculation,
$${m}_{c \to v}^{( ℓ - 1 )}$$
is a message transmitted from a check node to a variable node according to an (l−1)th iteration order of BP calculation,
$${γ}_{C}^{( ℓ )}$$
is a damping factor that determines how much a previous message value is reflected when updating a message, which is a weight trained as a real value greater than or equal to 0 and less than or equal to 1, and
$$( 1 - {γ}_{C}^{( ℓ )} )$$
is a term that determines how much a current message value is reflected when updating a message).

10. The method of claim 9, wherein the damping factor is set so as to allow different weights to be trained for each layer and node constituting each iteration order.

11. The method of claim 10, wherein the check nodes are set to be deactivated in an order of importance scores which are calculated based on trained damping factors.

12. The method of claim 2, wherein the separately setting operation comprises:
setting some of node groups included in a previous window and some of node groups included in a next window among nodes and edges of the neural network to overlap one another; and
setting a first weight set to be applied when a decoding result of the previous window is an error occurrence, and a second weight set to be applied when the decoding result of the previous window is normal to prevent an error occurring in a previous window from being propagated to a next window.

13. The method of claim 12, wherein the first weight set is set to be applied to transmitted messages when transmitting BP calculation information of a previous window to a next window in a case where an error is detected in the reliability information of the codeword in the BP calculation of the previous window.

14. The method of claim 12, wherein the second weight set is set to be applied to transmitted messages when transmitting BP calculation information of a previous window to a next window in a case where no error is detected in the reliability information of the codeword in the BP calculation of the previous window.

15. The method of claim 2, wherein the training data comprises:
reliability information on each bit of a codeword decoded from a received vector from a channel, and reliability information on each bit of an original codeword transmitted through the channel as correct data of the codeword.

16. The method of claim 15, wherein the reliability information comprises:
information on a log ratio between a probability that each bit constituting the target codeword is 1 and a probability that each bit is 0.

17. The method of claim 16, wherein the reliability information is expressed as Equation 6 below:
$${l}_{v} = log ( \frac{Pr ( {C}_{v} = 1 \vert {y}_{v} )}{Pr ( {C}_{v} = 0 \vert {y}_{v} )} ) \qquad [ Equation 6 ]$$
(Pr(Cᵥ=1|yᵥ) is a probability that a bit of an actual codeword is 1 when a value y received in a v-th bit is given, and Pr(Cᵥ=0|yᵥ) is a probability that the bit of the actual codeword is 0 when the value y received in the v-th bit is given).

18. The method of claim 1, wherein the supervised training operation comprises:
an operation of performing supervised training based on a loss function of Equation 6 below that trains all variable nodes within an entire window and a loss function of Equation 7 below that trains a target variable node,
$${L}_{A} = \frac{1}{2} [ 1 - sgn ( {min}_{1 \leq v \leq {WN}_{v}} {m}_{v}^{o} ) ] \qquad [ Equation 7 ]$$
(L_{A} is a loss function that trains total variable nodes, v is an index that specifies a variable node,
$${m}_{v}^{o}$$
is final reliability information of a variable node v, W is a number of variable node positions included in a window, and Nᵥ is a number of variable nodes at each position), and
$${L}_{T} = \frac{1}{2} [ 1 - sgn ( {min}_{1 \leq v \leq {TN}_{v}} {m}_{v}^{o} ) ] \qquad [ Equation 8 ]$$
(L_{T} is a loss function that trains a target variable node, v is an index that specifies a variable node,
$${m}_{v}^{o}$$
is final reliability information of a variable node v, W is a number of variable node positions included in a window, and Nᵥ is a number of variable nodes at each position).

19. An SC-LDPC-based decoding apparatus, the apparatus comprising:
a memory including an instruction; and
a processor that performs a predetermined operation based on the instruction,
wherein the operation of the processor comprises:
an operation of modeling a belief propagation (BP) message transmission process according to a preset number of iterations of BP calculations in a Tanner graph including check nodes, variable nodes, and messages between each node for SC-LDPC decoding as a layer of a neural network to generate a neural network-based LDPC decoder;
an operation of setting a damping factor that adjusts a ratio between a previous message and a current message transmitted from a check node to a variable node to determine whether to activate the check node in repeatedly carrying out BP calculations according to the number of iterations;
an operation of training a preset number of neural weight sets for a window, which is a unit in which a decoding process is performed, and separately setting a first weight set, which is used when a decoding result of the previous window is an error occurrence, and a second weight set, which is used when the decoding result of the previous window is normal, to mitigate error propagation between windows; and
an operation of training the decoder based on training data including information from a previous window.

20. A computer program stored on a computer-readable recording medium, the computer program comprising:
when performed on at least one processor,
an instruction that allows the processor to perform:
an operation of modeling a belief propagation (BP) message transmission process according to a preset number of iterations of BP calculations in a Tanner graph including check nodes, variable nodes, and messages between each node for SC-LDPC decoding as a layer of a neural network to generate a neural network-based LDPC decoder;
an operation of setting a damping factor that adjusts a ratio between a previous message and a current message transmitted from a check node to a variable node to determine whether to activate the check node in repeatedly carrying out BP calculations according to the number of iterations;
an operation of training a preset number of neural weight sets for a window, which is a unit in which a decoding process is performed, and separately setting a first weight set, which is used when a decoding result of the previous window is an error occurrence, and a second weight set, which is used when the decoding result of the previous window is normal, to mitigate error propagation between windows; and
an operation of training the decoder based on training data including information from a previous window.
